(19) United States
(12) Patent Application Publication
(10) Pub. No.: US 2020/0154213 A1
(43) Pub. Date: May 14, 2020

(54) TRANSDUCER

(71) Applicant: Yamaha Corporation, Hamamatsu (JP)

(72) Inventors: Tomoya MIYATA, Hamamatsu (JP); Akira MIKI, Hamamatsu (JP); Yu TSUCHIHASHI, Hamamatsu (JP)

(21) Appl. No.: 16/739,833

(22) Filed: Jan. 10, 2020

Related U.S. Application Data
(63) Continuation of application No. PCT/JP2018/018735, filed on May 15, 2018.

(30) Foreign Application Priority Data
Jul. 26, 2017 (JP) 2017-144971

(51) Int. Cl. H04R 17/00; H01L 41/053; H01L 41/047

(52) U.S. Cl. CPC H04R 17/00; H01L 41/047; H01L 41/053

(57) ABSTRACT

A transducer includes a housing, and a piezoelectric element that is disposed inside the housing and that has a porous film. The piezoelectric element is bent or curved.

### CROSS-REFERENCE TO RELATED APPLICATIONS

This application is a continuation application of International Application No. PCT/JP2018/018735, filed on May 15, 2018, which claims priority to Japanese Patent Application No. 2017-144971 filed in Japan on Jul. 26, 2017. The entire disclosures of International Application No. PCT/JP2018/018735 and Japanese Patent Application No. 2017-144971 are hereby incorporated herein by reference.

### BACKGROUND

### Technological Field

The present invention relates to a transducer.

### Background Information

Transducers using piezoelectric elements are widely used. This transducer is configured as a sound-generating device having, for example, a piezoelectric element that includes a piezoelectric film and a pair of electrodes laminated on both surfaces of the piezoelectric film, and a diaphragm that vibrates due to the transmission of the vibration of the piezoelectric element. In the transducer, the piezoelectric film vibrates due to the application of AC voltage to the pair of electrodes, and the diaphragm vibrates due to the transmission of the vibration. The transducer is configured to be capable of generating sound by means of the vibration of the diaphragm.

In addition, today, transducers using piezoelectric elements that are configured to generate sound directly by means of the vibration of the piezoelectric elements have been proposed (refer to Japanese Laid-open Patent Application No. 2015-91069).

The piezoelectric speaker disclosed in Japanese Laid-open Patent Application No. 2015-91069 comprises a multilayer piezoelectric body having a laminated body in which porous piezoelectric layers and internal electrodes are alternately laminated, and in which a pair of external electrodes are disposed on both sides of the laminated body in a direction perpendicular to the lamination direction. This piezoelectric speaker is configured such that, when voltage is applied to the external electrodes, the porous piezoelectric layers expand and contract in the lamination direction to thereby emit sound.

However, in the piezoelectric speaker disclosed in Japanese Laid-open Patent Application No. 2015-91069, the amplitude of the porous piezoelectric layers depends on the surface area of the multilayer piezoelectric body. Therefore, with the piezoelectric speaker, the size of the porous piezoelectric layer is increased in order to generate the desired sound. Accordingly, although the piezoelectric speaker can be used for relatively large speakers, it is difficult to employ in acoustic devices such as earphones and headphones, or in relatively small devices, such as mobile information terminals.

### SUMMARY

This disclosure was made in response to these circumstances, and an object of this disclosure is to provide a transducer that can be sufficiently reduced in size.

A transducer according to one aspect of this disclosure comprises a housing, and a piezoelectric element that is disposed inside the housing and that has a porous film. The piezoelectric element is bent or curved.

### BRIEF DESCRIPTION OF THE DRAWINGS

FIG. 1 is schematic cross-sectional view illustrating a transducer according to a first embodiment.

FIG. 2 is a schematic cross-sectional view illustrating a piezoelectric element of the transducer of FIG. 1.

FIG. 3 is a schematic cross-sectional view illustrating a transducer according to a second embodiment.

FIG. 4 is a schematic perspective view illustrating a covering member and a piezoelectric element of the transducer of FIG. 3.

FIG. 5 is a schematic perspective view illustrating a transducer according to a third embodiment

FIG. 6 is a schematic cross-sectional view of the transducer of FIG. 5.

FIG. 7 is a schematic perspective view illustrating a transducer according to a fourth embodiment.

FIG. 8 is a schematic perspective view illustrating a transducer according to a fifth embodiment.

FIG. 9 is a schematic cross-sectional view of the transducer of FIG. 8.

FIG. 10 is a schematic perspective view illustrating a piezoelectric element of a transducer according to another embodiment that is different form the first to fifth embodiments.

FIG. 11 is a schematic perspective view illustrating a supporting structure of a piezoelectric element of a transducer according to another embodiment that is different form the first to fifth embodiments and the embodiment as shown in FIG. 10.

### DETAILED DESCRIPTION OF THE EMBODIMENTS

An embodiment of this disclosure will be described in detail below, with reference to the drawings as deemed appropriate. It will be apparent to those skilled in the field from this disclosure that the following descriptions of the embodiments are provided for illustration only and not for the purpose of limiting the invention as defined by the appended claims and their equivalents.

A transducer according to a preferred embodiment comprises a housing, which forms an acoustic space, and a sheet-like piezoelectric element that is disposed inside the acoustic space and that has a porous film, wherein the piezoelectric element is bent or curved.

A pair of electrodes are preferably laminated on both sides of the porous film, and the pair of electrodes, which face each other, are preferably configured not to come into contact with each other due to the bending or the curving of the piezoelectric element.

The pair of opposing electrodes are preferably configured not to electrically short-circuit.

An insulating member is preferably interposed between the pair of opposing electrodes.

The piezoelectric element is preferably further bent or curved after being bent.

The piezoelectric element is preferably folded into multiple layers.

The layers that are adjacent due to the folding are preferably not in contact with each other.

A covering member that covers the piezoelectric element so as to be swingable is preferably provided.

The covering member is preferably a bag body.

A flexible support member that supports the piezoelectric element is preferably further provided and the bag body is preferably connected to the support member.

A core column that is connected to the housing is preferably further provided, and the piezoelectric element is preferably wound around the core column.

The “piezoelectric element is wound around the core column” here includes a configuration in which the innermost circumferential surface of the piezoelectric element is in contact with the outer circumferential surface of the core column, as well as a configuration in which the innermost circumferential surface of the piezoelectric element is spaced apart from the outer circumferential surface of the core column.

In the transducer according to the preferred embodiment, as a result of the piezoelectric element being bent or curved, it is possible to reduce the planar area of the piezoelectric element while ensuring sufficient surface area of the piezoelectric element. Therefore, in the transducer, it is possible to dispose this piezoelectric element in a housing with a relatively small planar area, while sufficiently increasing the surface area of the porous film. For example, when used as a sound-generating device, the transducer can generate sound by the expansion and contraction (vibration) of the porous film in the thickness direction. In addition, when the bent or curved piezoelectric element is disposed in an open space, the sound from the piezoelectric element in the sound emission direction and the sound from an area on the opposite side cancel each other out, so that it is difficult for there to be a contribution to the generation of music or voice. In contrast, if the piezoelectric element is disposed inside the acoustic space, all of the vibration accompanying the expansion/contraction of the porous film can be easily extracted as sound pressure. That is, it can be easily extracted as pressure changes inside the acoustic space. Therefore, the transducer can be sufficiently reduced in size, and to generate sufficient sound even when there is such a size reduction. The “surface area of the piezoelectric element” refers to the surface area of the piezoelectric element in plan view, in an unbent or uncurved expanded state. The “planar area of the piezoelectric element” refers to the area of the piezoelectric element in plan view in the bent or curved state.

### First Embodiment

### Transducer

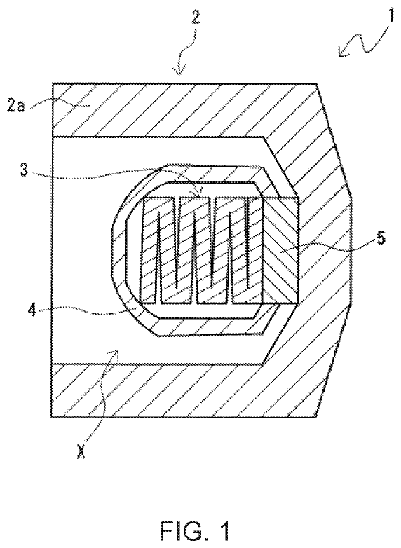

The transducer 1 of FIG. 1 is configured as a sound-generating device. The transducer 1 comprises a housing 2, which forms an acoustic space X, and a sheet-like piezoelectric element 3 that is disposed inside the acoustic space X and that has a porous film 11. In addition, the transducer 1 includes a bag body 4 as a covering member that covers the piezoelectric element 3 so as to be swingable, and a flexible support member 5 that supports the piezoelectric element 3. The acoustic space X is configured as a sealed space. The transducer 1 is a sound-generating device for audio equipment, and, more specifically, a sound-generating device for headphones provided in headphones. The housing “forms an acoustic space” means that an area in the housing forms an acoustic space when in use; for example, the area surrounded by the inner surface of the housing and the body of the user (the ear and the periphery of the ear) forms an acoustic space.

Housing

In the present embodiment, the housing 2 also serves as a headphone housing. The housing 2 has a bottomed cylindrical base portion 2a, and the piezoelectric element 3 is disposed inside the base portion 2a. An open end portion of the base portion 2a constitutes an attachment-side end portion that is attached to the user. In the present embodiment, the acoustic space X is preferably defined by the inner surface of the base portion 2a and the user's body (the car and periphery of the ear).

The lower limit of the volume of the acoustic space X formed by the base portion 2a is preferably 10 cm³, and more preferably 30 cm³. On the other hand, the upper limit of the volume of the acoustic space X is preferably 130 cm³ and more preferably 60 cm³. If the volume of the acoustic space X is less than the lower limit described above, it may be difficult to make the surface area of the piezoelectric element 3 disposed inside the base portion 2a sufficiently large. On the other hand, if the volume of the acoustic space X exceeds the upper limit described above, there is the risk that the base portion 2a will be unnecessarily large and that the usability of the device provided with the transducer 1 (the headphones in the present embodiment) will be reduced.

The lower limit of an average opening area of the open end portion of the base portion 2a is preferably 25 cm², more preferably 30 cm², and still more preferably 45 cm². On the other hand, the upper limit of the average opening area of the base portion 2a is preferably 65 cm², more preferably 55 cm², and still more preferably 50 cm². If the average opening area is less than the lower limit described above, it may be difficult to make the surface area of the piezoelectric element 3 disposed inside the base portion 2a sufficiently large. On the other hand, if the average opening area exceeds the upper limit described above, there is the risk that the base portion 2a will be unnecessarily large and that usability of the device provided with the transducer 1 will be reduced. The “average opening area of the base portion” means the average value of the area of a cross section of a hollow area (space) formed inside the cylindrical portion of the base portion, taken along a plane that is perpendicular to an axis of the cylindrical portion.

Piezoelectric Element

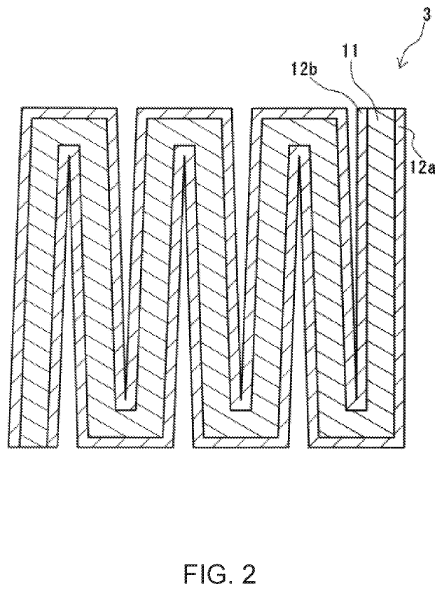

The piezoelectric element 3 has flexibility. As shown in FIG. 2, the piezoelectric element 3 has the porous film 11 and a pair of film-like electrodes 12a, 12b that are laminated on both sides of the porous film 11. The piezoelectric element 3 is a three-layer body in which the pair of electrodes 12a, 12b constitute the outermost layers. In addition, the piezoelectric element 3 has a terminal (not shown) to which a lead wire is connected that outputs an electric signal to the outside. The piezoelectric element 3 is configured as a sound-generating body and such that when an AC voltage is applied to the pair of electrodes 12a, 12b via the lead wire, the porous film 11 vibrates in the thickness direction to thereby emit sound.

The porous film 11 has flexibility. The porous film 11 is mainly composed of a synthetic resin such as polyethylene terephthalate, tetrafluoroethylene/hexafluoropropylene copolymer, and polypropylene. In addition, the porous film 11 is electretized by a polarization process. The method for the polarization process is not particularly limited; examples include a method in which a DC or a pulsed high voltage is applied to inject charge, a method in which ionizing radiation, such as y rays or electron beams, are irradiated to inject charge; and a method in which a corona discharge treatment is used to inject charge. The “main component” refers to the component of highest content, for example, the component with a content of 50 mass % or more.

The lower limit of the average thickness of the porous film 11 is preferably 10 μm, and more preferably 50 μm. On the other hand, the upper limit of the average thickness of the porous film 11 is preferably 500 μm, and more preferably 200 μm. If the average thickness is less than the lower limit described above, there is the risk that the strength (rigidity) of the porous film 11 will be insufficient, and, when the porous film 11 is bent or curved, as described further below, it will be difficult to maintain the bent or curved state. On the other hand, if the average thickness exceeds the upper limit described above, there is the risk that the weight of the porous film 11 will increase, and it will be difficult to maintain the desired attitude, depending on the bent or curved shape.

The material of the pair of electrodes 12a, 12b is not particularly limited as long as it is electrically conductive; examples include various metals such as aluminum, silver, gold, platinum, and copper, alloys of these metals, and carbon.

The average thickness of the pair of electrodes 12a, 12b can be at least 0.1 μm and up to 30 μm, depending on the lamination method. The pair of electrodes 12a, 12b has the function of a reinforcing part for maintaining the bent or curved shape of the porous film 11. In this regard, if the average thickness is less than the aforementioned lower limit, there is the risk that it will be difficult to sufficiently maintain the shape of the porous film 11. On the other hand, if the average thickness exceeds the aforementioned upper limit, there is the risk that peeling, tearing, etc., of the pair of electrodes 12a. 12b will tend to occur at the bent portion or curved portion of the porous film 11.

The piezoelectric element 3 is bent or curved. In addition, the piezoelectric element 3 has appropriate rigidity and is provided such that the bent or curved state is not impaired even when the porous film 11 vibrates. The bent or curved shape of the piezoelectric element 3 is not particularly limited; examples include bent or curved shapes achieved by means of zigzag folding, cross folding, winding folding, and roll folding. However, since it is necessary for one electrode 12a not to be in physical contact with the other electrode 12b in the bent or curved state, the piezoelectric element 3 is preferably bent by means of zigzag folding, as a configuration in which physical contact between the one electrode 12a and the other electrode 12b is not likely to occur. Here, “physical contact” means a state in which a pair of opposing electrodes 12a and 12b that face to each other in the bent or curved state come into contact with each other, which causes inhibition of the expansion/contraction of the porous film and/or causes decreasing of surface area of the piezoelectric element 3, and a state in which the pair of opposing electrodes unintendedly come into electrical contact with each other. When the transducer 1 is bent by means of zigzag folding, cross folding, winding folding, roll folding, etc., electrical contact between the one electrode 12a and the other electrode 12b can be prevented by interposing an insulating member between the opposing one electrode 12a and the other electrode 12b. In addition, said insulating member can be formed having a thin film shape so as to not inhibit the sound generation of the piezoelectric element 3 or can be partially disposed between the pair of electrodes 12a. 12b so as to maintain the space between the pair of electrodes 12a, 12b.

The lower limit of the surface area of the piezoelectric element 3 is preferably 100 cm², more preferably 500 cm², and still more preferably 700 cm². On the other hand, the upper limit of the surface area of the piezoelectric element 3 is preferably 1500 cm², more preferably 1200 cm², and still more preferably 1000 cm². If the surface area is less than the lower limit described above, there is the risk that the amplitude of the porous film 11 cannot be sufficiently increased. On the other hand, if the surface area exceeds the upper limit described above, there is the risk that the piezoelectric element 3 will be unnecessarily large and that usability of the device provided with the transducer 1 will be reduced.

The surface shape of the piezoelectric element 3 is not particularly limited, but is preferably rectangular. The amplitude of the porous film 11 depends on the length of the surface of the porous film 11. Accordingly, by making the surface shape of the piezoelectric element 3 rectangular and making the longitudinal length of the piezoelectric element 3 relatively long, it is a simple matter to increase the amplitude of the porous film 1. In addition making the surface shape of the piezoelectric element 3 rectangular facilitates bending the piezoelectric element 3 by means of zigzag folding, winding folding, cross folding, roll folding, or the like, such that the bent portion is formed along the lateral direction.

If the surface shape of the piezoelectric element 3 is rectangular, the lower limit of the longitudinal length of the piezoelectric element 3 is preferably 10 cm, more preferably 25 cm, and still more preferably 40 cm. On the other hand, the upper limit of the longitudinal length of the piezoelectric element 3 is preferably 100 cm, more preferably 90 cm, and still more preferably 80 cm. If the longitudinal length is shorter than the aforementioned lower limit, there is the risk that the amplitude of the porous film 11 cannot be sufficiently increased. On the other hand, if the longitudinal length exceeds the aforementioned upper limit, there is the risk that it will be difficult to maintain the attitude of the piezoelectric element 3 in the bent or curved state.

The piezoelectric element 3 is preferably folded into multiple layers. In particular, the piezoelectric element 3 is preferably folded into multiple layers by means of zigzag folding. In the transducer 1, folding the piezoelectric element 3 into multiple layers makes it possible to make the surface area of the piezoelectric element 3 sufficiently large and to house the piezoelectric element 3 in the acoustic space X. In particular, in the transducer 1, folding the piezoelectric element 3 into multiple layers by means of zigzag folding makes it possible to increase the longitudinal length of the piezoelectric element 3 and to increase the amplitude of the porous film 11, as well as to easily and reliably prevent electrical contact between the one electrode 12a and the other electrode 12b.

When the piezoelectric element 3 is folded into multiple layers, the lower limit of the number of layers of the piezoelectric element 3 is preferably 3, and more preferably 5. On the other hand, the upper limit of the number of layers of the piezoelectric element 3 is preferably 10, and more preferably 8. If the number of layers is less than the aforementioned lower limit, there is the risk it will be difficult to make the surface area of the piezoelectric element 3 sufficiently large. On the other hand, if the number of layers exceeds the upper limit described above, there is the risk that the attitude of the piezoelectric element 3 will become unstable.

The lower limit of the planar area of the piezoelectric element 3 in a folded multiple layer state is preferably 1 cm², and more preferably 4 cm². On the other hand, the upper limit of the aforementioned planar area is preferably 65 cm², and more preferably 40 cm². If the planar area is less than the aforementioned lower limit, there is the risk that it will be difficult to make the surface area of the piezoelectric element 3 sufficiently large in a state in which the piezoelectric element 3 is maintained in the desired attitude. On the other hand, if the planar area exceeds the aforementioned upper limit, there is the risk that the size of the transducer 1 will be too large and that the usability of the device provided with the transducer 1 will be reduced.

When the piezoelectric element 3 is folded into multiple layers, layers that are adjacent to each other due to the folding are preferably not in contact with each other. As a result of the layers that are adjacent to each other due to the folding not being in contact with each other, it becomes possible to increase the amplitude of the porous film 11 in each layer and to make the amplitude of the entire porous film 11 sufficiently large. In the transducer 1, all of the layers that are adjacent to each other due to the folding are preferably not in contact with each other across the entire surface. However, in the case that the piezoelectric element 3 is folded into multiple layers in the transducer 1, the end portion on the side supported by the support member 5 (terminal portion), when the piezoelectric element 3 is viewed in the longitudinal direction, can be folded back toward the support member 5 side in order to prevent short-circuiting of the terminals. In this case, the terminal portion can be in contact with the adjacent layer. In addition, in order to prevent an electrical short circuit between the pair of electrodes 12a. 12b, the piezoelectric element 3 can be once folded in half such that one of the electrodes is not exposed, and then folded into multiple layers. In this manner, by folding the piezoelectric element 3 after folding such that one of the electrodes is not exposed, it becomes possible reliably to prevent short-circuiting between the pair of electrodes 12a, 12b.

In the transducer 1, in order to suppress peeling of the pair of electrodes 12a, 12b at the bent portion or the curved portion of the piezoelectric element 3 and to facilitate the maintenance of the attitudes of these portions, reinforcement materials can be laminated on the inner surfaces and/or outer surfaces of these portions. An example of a reinforcement material includes a synthetic resin sheet.

Bag Body

The bag body 4 covers the piezoelectric element 3 so as not to restrict the vibration of the porous film 11 in the thickness direction. An opening-side end of the bag body 4 is connected to the support member 5. As a result, the piezoelectric element 3 is surrounded by the bag body 4 and the support member 5. In addition, the bag body 4 covers the outer surface of the piezoelectric element 3 so as to be in contact with a portion of the outer surface of the piezoelectric element 3 and thereby suppresses the attitude of the piezoelectric element 3 from becoming unintendedly deformed. Making the covering member that covers the piezoelectric element 3 of the transducer 1 swingable facilitates holding the piezoelectric element 3 in the desired attitude in the bent or curved state. In addition, since the covering member is the bag body 4 in the transducer 1, the covering member suppresses physical interference with respect to the porous film 11; more specifically, the covering member suppresses a reduction in the surface area of the piezoelectric element 3 as a result of the opposing electrodes 12a, 12b coming into contact with each other due to the zigzag structure, or the opposing electrodes 12a, 12b coming into contact with each other to inhibit the expansion/contraction of the porous film 11, so that the sound emitted from the piezoelectric element 3 can be of sufficient volume.

The bag body 4 has stretchability. In addition, the bag body 4 preferably has flexibility. Moreover, the bag body 4 preferably has a plurality of openings so that the transmission of the vibration of the porous film 11 is not inhibited. The bag body 4 is formed from a stretchable mesh, for example. The material of the bag body 4 is preferably a fiber that is not electrically conductivity and has a relatively low specific gravity; examples include polyolefin fibers such as polyethylene fibers and polypropylene fibers, polyester fibers such as polyethylene terephthalate fibers, polytrimethylene terephthalate fibers, polybutylene terephthalate fibers, and polylactic acid fibers, polyurethane elastic fibers (spandex), polycarbonate fibers, polystyrene fibers, polyphenylene sulfide fibers, and fluorine resin fibers. Of the foregoing, polyurethane elastic fibers, which have excellent stretchability, are preferable.

Support Member

The support member 5 has flexibility. Flexibility of the support member 5 suppresses transmission of the vibration of the porous film 11 to the housing 2. The support member 5 has a bottom surface and a supporting surface, which are arranged parallel to each other, and the piezoelectric element 3 is supported by the supporting surface. As a result, the piezoelectric element 3 does not directly contact the housing 2. Overall, the support member 5 has the formed of a rectangular parallelepiped. The bottom surface of the support member 5 is fixed to the housing 2, more specifically, to the bottom portion of the base portion 2a. In addition, the opening-side end of the bag body 4 is connected to a side surface of the support member 5. Since the transducer 1 has the support member 5 that supports the piezoelectric element 3, and the bag body 4 is connected to this support member 5, it is possible to surround the piezoelectric element 3 with the support member 5 and the bag body 4; and it is thus possible to hold the piezoelectric element 3 in the desired attitude in the bent or curved state.

The piezoelectric element 3 can or cannot be fixed to the supporting surface of the support member 5. If the piezoelectric element 3 is not fixed to the support member 5, suppression of the reduction in the vibration characteristics of the outermost layer of the piezoelectric element 3 on the support member 5 side can be facilitated. On the other hand, if the piezoelectric element 3 is fixed to the support member 5, the attitude of the piezoelectric element 3 becomes more stable. If the piezoelectric element 3 is fixed to the support member 5, for example, the entire outer surface of the piezoelectric element 3 that opposes the supporting surface can be fixed to the supporting surface, or the outer surface can be fixed to the supporting surface in a sporadic manner.

The material forming the support member 5 is not particularly limited as long as the material has flexibility and can stably hold the piezoelectric element 3 on the supporting surface side; examples include felt, nonwoven fabric, and synthetic resin. Of the foregoing, felt, which has excellent flexibility and shape stability in a state in which the piezoelectric element 3 is disposed thereon, is preferable.

### Advantages

The transducer 1 can generate sound by the expansion and contraction (vibration) of the porous film 11 in the thickness direction. In the transducer 1, because the piezoelectric element 3 is bent or curved, it is possible to reduce the planar area (area in plan view) of the piezoelectric element 3 while ensuring sufficient surface area of the piezoelectric element 3. Therefore, in the transducer 1, it is possible to dispose the piezoelectric element 3 in the housing 2 with a relatively small planar area, while sufficiently increasing the amplitude of the porous film 11. In addition, when the bent or curved piezoelectric element is disposed in an open space, the sound from the piezoelectric element in the sound emission direction and the sound from an area on the opposite side cancel each other out, so that it is difficult for there to be a contribution to the generation of music or voice. In contrast, if the piezoelectric element 3 is disposed inside the acoustic space X, all of the vibration accompanying the expansion/contraction of the porous film 11 can be easily extracted as sound pressure. That is, the vibration can be easily extracted as changes in pressure inside the acoustic space X. Therefore, the transducer 1 can generate sufficient sound even when reduced in size.

In addition, since the bag body 4 covers the piezoelectric element 3 so as to be swingable in the transducer 1, the vibration of housing 2 will not tend to become noise. In particular, since the porous film 11 in the transducer 1 is relatively light, it is possible to more easily suppress the vibration of the housing 2 from turning into noise.

### Second Embodiment

### Transducer

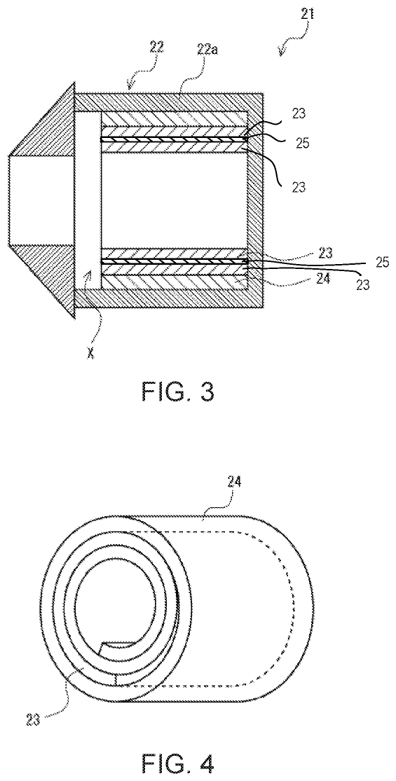

A transducer 21 of FIG. 3 is configured as a sound-generating device. The transducer 21 comprises a housing 22, which forms the acoustic space X, and a sheet-like piezoelectric element 23 that is disposed inside the acoustic space X and that has a porous film. In addition, the transducer 21 has a covering member 24 that covers the piezoelectric element 23 so as to be swingable. The transducer 21 is a sound-generating device for audio equipment, and, more specifically, a sound-generating device for earphones provided in an earphone.

Housing

In the present embodiment, the housing 22 also serves as an earphone housing. The housing 22 has a bottomed cylindrical base portion 22a, and the piezoelectric element 23 is disposed inside the base portion 22a. The base portion 22a is configured such that the open side is positioned on the attachment side that is attached to the user. The internal volume of the base portion 22a can be the same as the internal volume of the base portion 2a in FIG. 1, but can be made smaller than the internal volume of the base portion 2a in FIG. 1 to match the size of the earphone. The internal volume of the base portion 22a, when smaller than the internal volume of the base portion 2a in FIG. 1, can be set to, for example, 0.03 cm³ or more and 2 cm³ or less.

Piezoelectric Element

The piezoelectric element 23 has flexibility. In the same manner as the piezoelectric element 3 of FIG. 2, the piezoelectric element 23 has the porous film and a pair of film-like electrodes that are laminated on both sides of the porous film. The piezoelectric element 23 is a three-layer body in which the pair of electrodes constitute the outermost layers. The material and the average thicknesses of the pair of electrodes and the porous film of the piezoelectric element 23 can be the same as for the piezoelectric element 3 of FIG. 2.

The piezoelectric element 23 is curved and is specifically wound in a roll shape. Specifically, the surface shape of the piezoelectric element 23 is rectangular and is wound in a roll shape such that the longitudinal direction is the winding direction. An insulating member 25 can be interposed between each of the layers of the piezoelectric element 23 such that one of the electrodes does not come into electrical contact with the other electrode. In addition, the radially outside end portion of the piezoelectric element 23 on which the terminal is formed can be folded back toward the covering member 24 side, in order to prevent short-circuiting of the terminals. In addition, in order to prevent an electrical short circuit between the pair of electrodes, the piezoelectric element 23 can be temporarily folded in half, such that one of the electrodes is not exposed, and then folded into a roll shape. In this manner, by winding the piezoelectric element 23 after folding such that one of the electrodes is not exposed, it becomes possible reliably to prevent the short-circuiting of the pair of electrodes.

The surface area of the piezoelectric element 23 can be the same as the surface area of the piezoelectric element 3 of FIG. 2, but can be made smaller than the surface area of the piezoelectric element 3 to match the size of the earphone. The surface area of the piezoelectric element 23, when smaller than the surface area of the piezoelectric element 3 of FIG. 2, can be, for example, at least 2 cm² and up to 15 cm².

The lower limit of the average diameter of the outer circumferential surface of the piezoelectric element 23 in the curved state is preferably 3 mm, and more preferably 5 mm. On the other hand, the upper limit of the average diameter described above is preferably 15 mm, and more preferably 10 mm. If the average diameter is smaller than the aforementioned lower limit, there is the risk that the amplitude of the porous film will not be sufficiently increased. On the other hand, if the average diameter exceeds the aforementioned upper limit, there is the risk that the size of the housing 22 that houses the piezoelectric element 23 will be too large and that it will be difficult to apply the transducer 21 to the earphone.

The longitudinal length of the piezoelectric element 23 can be the same as the longitudinal length of the piezoelectric element 3 of FIG. 2, but can be made shorter than the longitudinal length of the piezoelectric element 3 to match the size of the earphone. The longitudinal length of the piezoelectric element 23, when shorter than the longitudinal length of the piezoelectric element 3 of FIG. 2, can be, for example, at least 2 cm and up to 15 cm.

Covering Member

As shown in FIG. 4, the covering member 24 is formed with a cylindrical shape and supports the outer circumferential surface of the piezoelectric element 23 in a wound state from the outside. The covering member 24 thereby suppresses the unintended deformation of the attitude of the piezoelectric element 23. The covering member 24 has flexibility and is interposed between the piezoelectric element 23 and the housing 22. As a result the piezoelectric element 23 does not directly come into contact with the housing 22. The interposing of the covering member 24 between the piezoelectric element 23 and the housing 22 suppresses the transmission of the vibration of the porous film to the housing 22. Because the transducer 21 has a covering member 24 that covers the piezoelectric element 23 so as to be swingable, holding the piezoelectric element 23 in the desired attitude in the curved state is facilitated. The covering member 24 can be formed from a stretchable mesh like the bag body 4 of FIG. 1, for example, or be formed from a foam (sponge). In addition, in the same manner as the bag body 4 of FIG. 1, the covering member 24 can have a plurality of openings.

### Advantages

In the transducer 21, since the piezoelectric element 23 is curved, it is possible to ensure sufficient surface area of the piezoelectric element 23. It is thereby possible to dispose the piezoelectric element 23 in the housing 22 with a relatively small planar area, while sufficiently increasing the amplitude of the porous film. Therefore, the transducer 21 can generate sufficient sound even when reduced in size.

### Third Embodiment

### Transducer

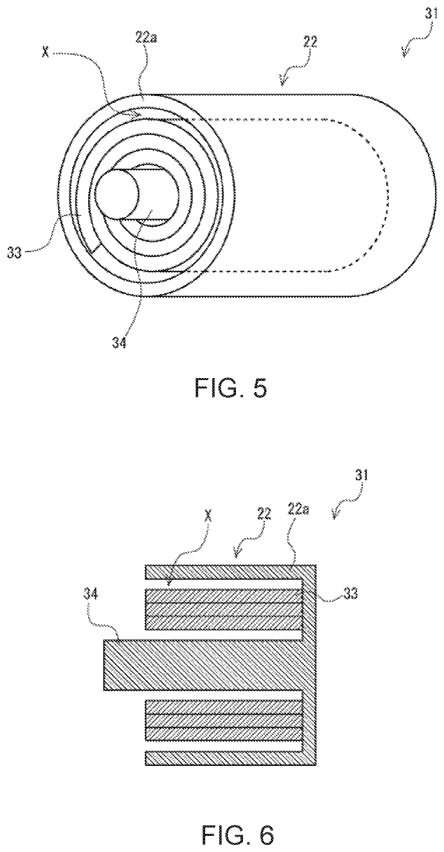

A transducer 31 of FIGS. 5 and 6 is configured as a sound-generating device. The transducer 31 comprises the housing 22, which forms the acoustic space X, and a sheet-like piezoelectric element 33 that is disposed inside the acoustic space X and that has a porous film. The transducer 31 has a core column 34 that is connected to the housing 22. The transducer 31 is a sound-generating device for audio equipment, and, more specifically, a sound-generating device for earphones provided in an earphone. Since the housing 22 of the transducer 31 is the same as the housing 22 of the transducer 21 of FIG. 3, the same reference symbol has been assigned and the description thereof is omitted

The piezoelectric element 33 is curved and, specifically, is wound in a roll shape. An insulating member can be interposed between each of the layers of the piezoelectric element 33 such that one of the electrodes does not come into electrical contact with the other electrode. In addition, the radially outside end portion of the piezoelectric element 33 on which the terminal is formed can be folded back in order to prevent short-circuiting of the terminals. The specific configuration of the piezoelectric element 33 can be the same as that of the piezoelectric element 23 of the transducer 21 of FIG. 3.

The core column 34 is configured in a rod shape, more specifically, in a columnar or a polygonal column shape. The core column 34 is composed of a rigid member. The core column 34 projects from the inner surface of the base portion 22a of the housing 22 toward the release side (open side) in the axial direction of the housing 22. The core column 34 can be formed separately from the base portion 22a and fixed to the base portion 22a, but is preferably integrally formed with the base portion 22a. The distal end portion of the core column 34 projects outwardly from the end portion of the open side of the base portion 22a. For example, an carpiece (not shown) is connected to the distal end portion of the core column 34.

In the transducer 31, the piezoelectric element 33 is wound around the core column 34. The piezoelectric element 33 is preferably not fixed to the core column 34 and the base portion 22a.

### Advantages

In the transducer 31, the piezoelectric element 33 is disposed inside the base portion 22a in a state in which the piezoelectric element 33 is wound around the core column 34, such that it is possible to ensure sufficient surface area of the piezoelectric element 33 while making the average diameter thereof small. As a result, it is possible to sufficiently increase the amplitude of the porous film in the transducer 31. In addition, in the transducer 31, since the base portion 22a is released (open) on only one side, all of the vibration accompanying the expansion/contraction of the porous film can be easily extracted as sound pressure from the open end side. Accordingly, the transducer 31 can generate sufficient sound even when reduced in size.

### Fourth Embodiment

### Transducer

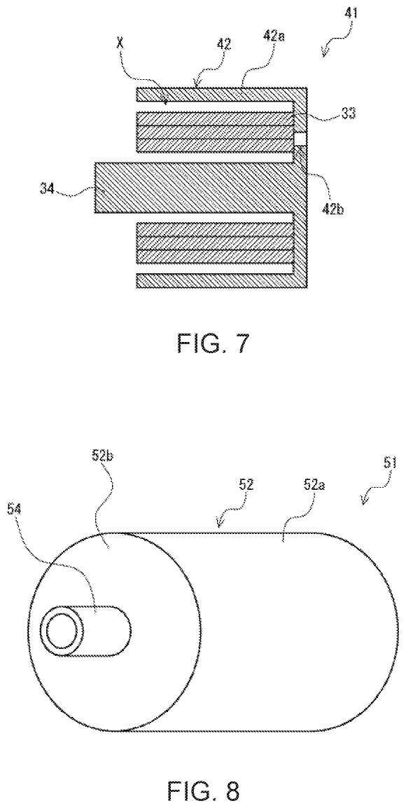

A transducer 41 of FIG. 7 is configured as a sound-generating device. The transducer 41 comprises a housing 42, which forms the acoustic space X, and the sheet-like piezoelectric element 33 that is disposed inside the acoustic space X and that has a porous film. The transducer 41 has the core column 34 that is connected to the housing 42. The transducer 41 is a sound-generating device for audio equipment, and, more specifically, a sound-generating device for earphones provided in an earphone. In the transducer 41, a through-hole 42b is formed penetrating a base portion 42a of the housing 42 in the thickness direction. Except for the formation of the through-hole 42b in the base portion 42a of the housing 42, the transducer 41 has the same configuration as that of the transducer 31 of FIG. 5.

The through-hole 42b is configured to be capable of transmitting external vibration to the inside of the housing 42 that forms the acoustic space X, more specifically, to the inside of the base portion 42a. The through-hole 42b is formed at the bottom of the base portion 42a. The average diameter and the number of the through-holes 42b can be adjusted as required such that the frequency of the vibration to be taken into the acoustic space X can be adjusted to the desired range.

### Advantages

Since the through-hole 42b, which is capable of transmitting external vibration into the housing 42, is formed, the transducer 41 is able to adjust the tone and volume, such as amplifying low-frequency sounds, by means of Helmholtz resonance based on the through-hole 42b.

### Fifth Embodiment

### Transducer

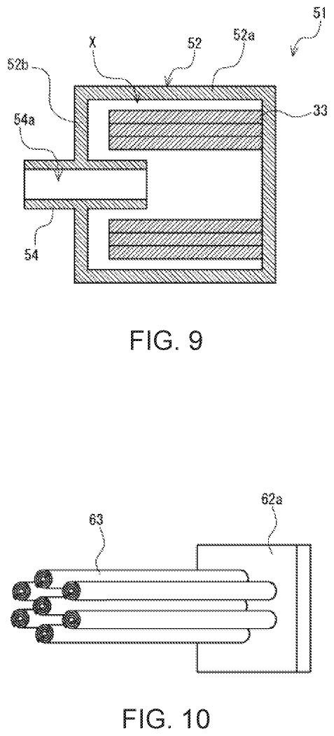

A transducer 51 of FIGS. 8 and 9 is configured as a microphone. The transducer 51 comprises a housing 52, which forms the acoustic space X. and the sheet-like piezoelectric element 33 that is disposed inside the acoustic space X and that has a porous film. The transducer 51 has a core column 54 that is connected to the housing 52. Since the piezoelectric element 33 of the transducer 51 is the same as the piezoelectric element 33 of the transducer 31 of FIG. 5, the same reference symbol has been assigned and the description thereof is omitted

The housing 52 has a box-shaped base portion 52a having an internal space. Specifically, the base portion 52a can be configured by scaling the open end portion of the base portion 22a of the transducer 21 in FIG. 3 with a lid portion 52b. In the transducer 51, the internal space of the base portion 52a is configured as the acoustic space X.

The core column 54 is configured in a tubular shape. That is, a through-hole 54a is formed inside the core column 54 across the two axial ends. The core column 54 penetrates the lid portion 52b in the thickness direction. The core column 54 projects inwardly into and outwardly from the lid portion 52b. An opening of the distal end of the core column 54 that projects toward the inner surface side of the lid portion 52b is open to the acoustic space X. In addition, an opening of the distal end of the core column 54 that projects toward the outer surface side of the lid portion 52b is open to the outside air.

In the transducer 51, the piezoelectric element 33 is wound around the core column 54. The piezoelectric element 33 is preferably not fixed to the core column 54 and the base portion 52a.

### Advantages

Since the through-hole 54a that is capable of transmitting external vibration is formed in the transducer 51, it is possible to adjust the frequency of the Helmholtz resonance, by, for example, adjusting the arrangement position of the core column 54 with respect to the lid portion 52b. Therefore, when the transducer 51 is used as a microphone, it is possible to adjust to a desired frequency characteristic by means of the resonance frequency of the acoustic space X.

### Other Embodiments

The above-described embodiment does not limit the configuration of the above-described embodiments. Therefore, in the above-described embodiments, the compositional elements of each part of the embodiment may be omitted, replaced, or added to based on the recitation of the present Specification and common knowledge of the art, all of which shall be interpreted as belonging to the scope of this disclosure.

For example, as shown in FIG. 10, the transducer can be provided with a plurality of piezoelectric elements 63, each wound in a roll shape, projecting from a base portion 62a of the housing. In addition, in this case, a plurality of core columns (not shown) that are wound around each of the piezoelectric elements 63 can also be provided, and a frame body (not shown) for partitioning each of the piezoelectric elements 63 can also be provided. The transducer of FIG. 10 can be used as an array speaker by arranging a plurality of closely and tightly wound piezoelectric elements 63 in an array.

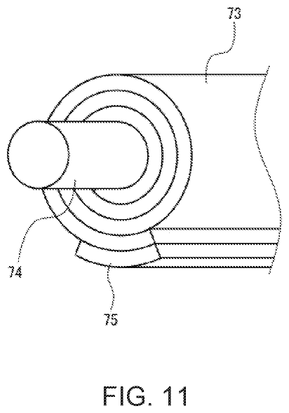

In addition, as shown in FIG. 11, in a piezoelectric element 73, the inner surface of the innermost circumferential end portion that is wound in a roll shape can be fixed to a core column 74, and the outer surface of the outermost circumferential end portion can be fixed to a support member 75. The support member 75 can be rigid or flexible. It is possible in this way to tightly wind the piezoelectric element 73 by fixing the innermost circumferential side end portion and/or the outermost circumferential side end portion of the piezoelectric element 73 and not fixing the portions other than these endmost portions. In addition, by means of this configuration, since the piezoelectric element 73 is released sufficiently radially outward, the porous film easily expands and contracts in the thickness direction.

As long as the piezoelectric element can maintain the bent or curved state, the transducer need not require the covering member described above, for example, as in the configurations of FIGS. 1 and 3. In addition, for example, in the configurations of FIGS. 5, 7, 8, 10, and 11, the transducer can have a covering member that covers the piezoelectric element so as to be swingable.

Even if the transducer has a core column that is connected to the housing, the piezoelectric element cannot need to be wound around the core column. In addition, even when the piezoelectric element is wound around the core column, the piezoelectric element can be wound around the core column in a state of being folded, for example, in the form of a bellows (zigzag shape). Moreover, it is not necessary that the piezoelectric element be wound around the core column such that the cross section in the direction perpendicular to the axis has an annular shape, for example, the piezoelectric element can be wound around the core column such that the cross section in the direction perpendicular to the axis has a polygonal ring shape. In addition, the piezoelectric element can be wound around the core column in a spiral shape.

The core column can be composed of an elastic member so as to be capable of curving when required.

In the case in which the transducer is configured as a microphone, in the above-described embodiment, an example was described in which external vibration is transmitted to the acoustic space through only the through-hole of the core column. In this regard, a through-hole for transmitting the external vibration to the acoustic space can also be formed in the transducer at the bottom of the base portion, in addition to the through-hole of the core column.

For example, the transducer can be configured as a sound-generating device other than headphones, earphones, or speakers, or configured as another type of acoustic equipment.

As described above, because the transducer of this disclosure can be sufficiently reduced in size, the transducer is suitable for use in a small acoustic equipment, such as headphones, earphones, and microphones.

What is claimed is:

1. A transducer comprising:
a housing; and
a piezoelectric element that is disposed inside the housing and that has a porous film,
the piezoelectric element being bent or curved.

2. The transducer according to claim 1, wherein
the piezoelectric element further has a pair of electrodes that are laminated on both sides of the porous film, and
the pair of electrodes which face to each other due to bending or curving of the piezoelectric element are configured not to come into contact with each other.

3. The transducer according to claim 2, wherein
the pair of electrodes which face to each other are configured not to electrically short-circuit.

4. The transducer according to claim 3, further comprising
an insulating member that is interposed between the pair of electrodes which face to each other.

5. The transducer according to claim 3, wherein
the piezoelectric element is further bent or curved after being bent.

6. The transducer according to claim 1, wherein
the piezoelectric element is folded into multiple layers.

7. The transducer according to claim 6, wherein
adjacent layers of the piezoelectric element that are adjacent due to folding of the piezoelectric element are not in contact with each other.

8. The transducer according to claim 1, further comprising
a covering member that covers the piezoelectric element.

9. The transducer according to claim 8, wherein
the covering member is a bag body.

10. The transducer according to claim 9, further comprising
a flexible support member that supports the piezoelectric element and to which the bag body is connected.

11. The transducer according to claim 1, further comprising
a core column that is connected to the housing and around which the piezoelectric element is wound.
